(19) United States
(12) Patent Application Publication
(10) Pub. No.: US 2015/0370179 A1
(43) Pub. Date: Dec. 24, 2015

(54) MASK CASE AND INSPECTION METHOD

(71) Applicant: Kabushiki Kaisha Toshiba, Minato-ku (JP)

(72) Inventor: Masaru SUZUKI, Kuwana (JP)

(73) Assignee: Kabushiki Kaisha Toshiba, Minato-ku (JP)

(21) Appl. No.: 14/475,646

(22) Filed: Sep. 3, 2014

Related U.S. Application Data
(60) Provisional application No. 62/015,283, filed on Jun. 20, 2014.

(51) Int. Cl. G03F 7/20

(52) U.S. Cl. CPC G03F 7/70733

(57) ABSTRACT

According to one embodiment, there is provided a mask case to house a mask for an exposure apparatus. The mask case has a dug area in its part to face a pattern of the mask.

### CROSS-REFERENCE TO RELATED APPLICATIONS

This application is based upon and claims the benefit of priority from U.S. Provisional Application No. 62/015,283, filed on Jun. 20, 2014; the entire contents of which are incorporated herein by reference.

### FIELD

Embodiments described herein relate generally to a mask case and an inspection method.

### BACKGROUND

If particles attach to the pattern of a mask, the production yield of semiconductor devices manufactured using the mask is affected adversely. Accordingly, it is desired to check highly accurately whether or not particles are attaching to the pattern of a mask.

### [Disclosure of Invention]

### BRIEF DESCRIPTION OF THE DRAWINGS

FIG. 1 is a diagram showing the configuration of a mask case and the way of housing a mask according to a first embodiment;

FIG. 2 is a diagram showing the configuration of an inner pod in the first embodiment;

FIG. 3 is a diagram showing a cross-sectional configuration of a dug area in the first embodiment;

FIG. 4 is a diagram showing an exposure apparatus in which a mask is used in the first embodiment;

FIG. 5 is a figure showing particles' attaching to the mask in the first embodiment;

FIG. 6 is a flow chart showing the usage method and inspection method of the mask case according to the first embodiment;

FIG. 7 is a diagram showing the inspection method of the mask case according to the first embodiment;

FIG. 8 is a diagram showing the configuration of an inspection apparatus in the first embodiment; and

FIG. 9 is a diagram showing the inspection method of a mask case according to a second embodiment.

### DETAILED DESCRIPTION

In general, according to one embodiment, there is provided a mask case to house a mask for an exposure apparatus. The mask case has a dug area in its part to face a pattern of the mask.

Exemplary embodiments of a mask case will be explained below in detail with reference to the accompanying drawings. The present invention is not limited to the following embodiments.

### First Embodiment

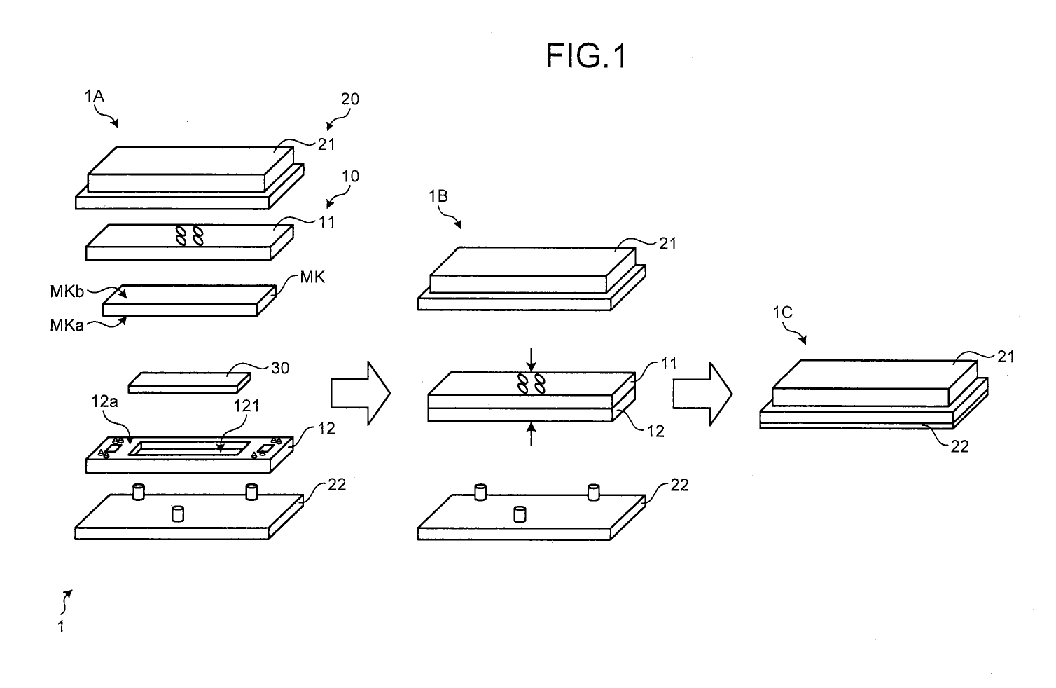

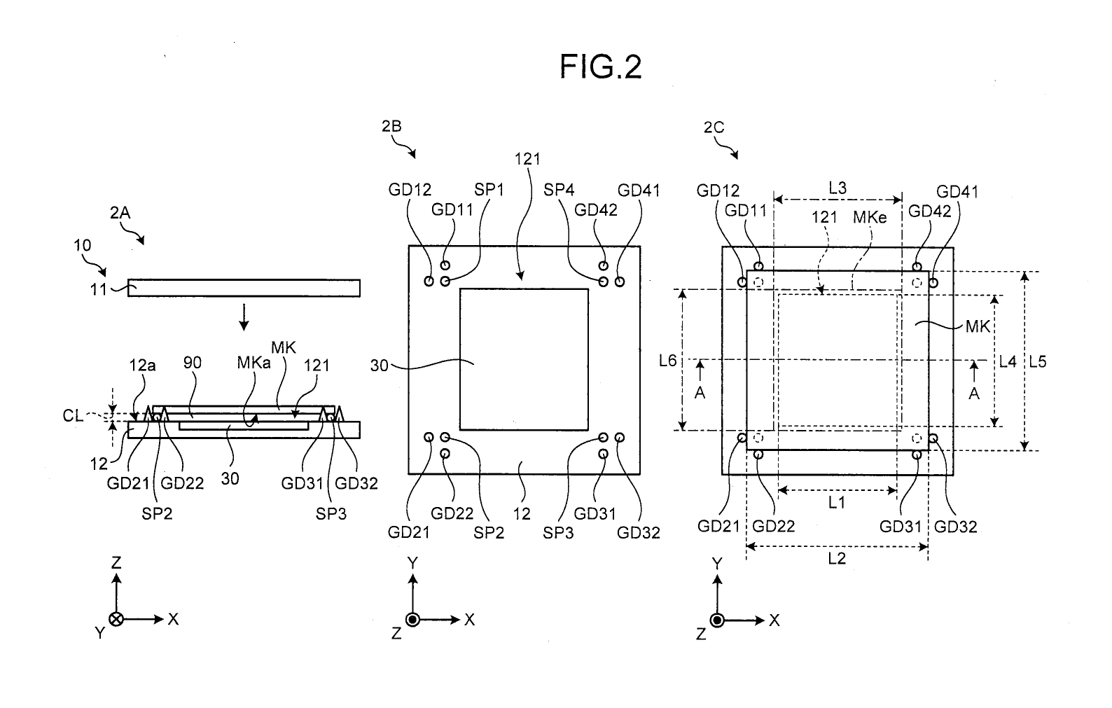

A mask case 1 according to the first embodiment will be described using FIGS. 1 and 2. FIG. 1 is a diagram showing the configuration of the mask case 1. FIG. 2 is a diagram showing the configuration of an inner pod 10.

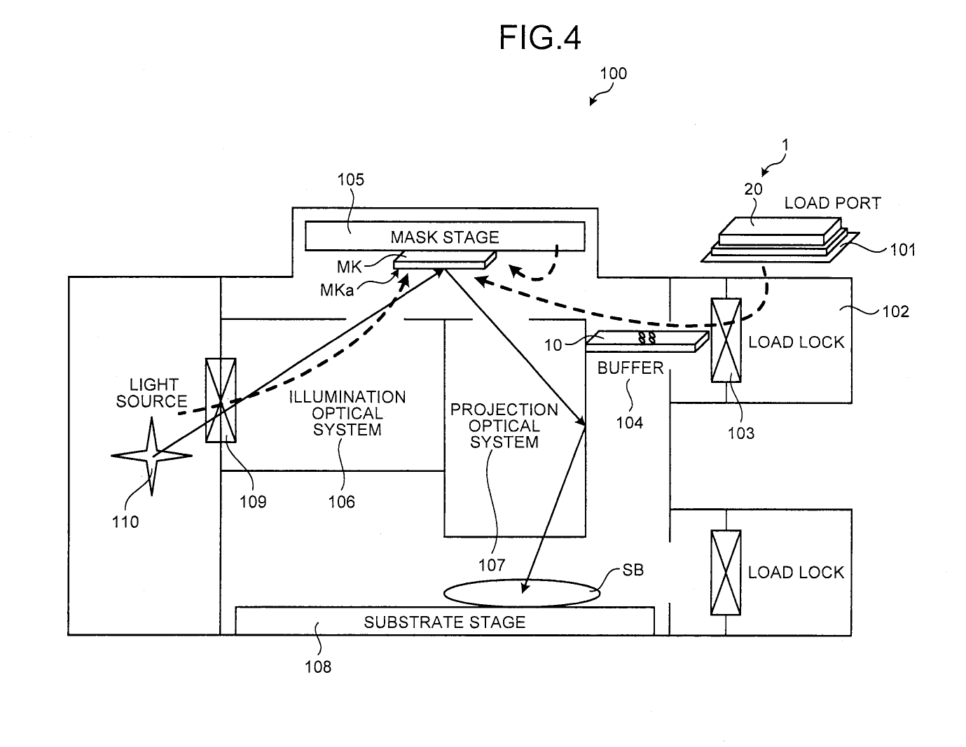

The mask case 1 houses a mask MK to be used in an exposure apparatus in a semiconductor manufacturing process. Specifically, as semiconductor device features become finer, light sources used in exposure apparatuses become further shorter in wavelength, and thus exposure apparatuses (EUV exposure apparatuses) using extreme ultraviolet light (EUV light) of a wavelength of about 100 nm or less are beginning to be applied to semiconductor devices. With an EUV exposure apparatus 100 (see FIG. 4), because the wavelength of exposure light is very short, a lens material (of high transmittance and refractive index difference) suitable to form a refraction optical system does not exist, and thus a reflection optical system and reflective masks MK need to be used.

The reflective mask MK has a Mo/Si multilayer laid on a pattern surface MKa side thereof to reflect EUV light. The reflective mask MK has a pattern of absorbers to absorb EUV light formed on the Mo/Si multilayer and in an exposure feasible area MKe (shown in 2C of FIG. 2) in the pattern surface MKa. In the EUV exposure apparatus 100 (see FIG. 4), EUV light irradiated onto the pattern surface MKa of the mask MK is reflected by the pattern, and the pattern of the mask MK, in the form of an image of the reflected light, is transferred onto a substrate, thus finishing an exposure of the substrate. This exposure is performed in a vacuum chamber of the exposure apparatus in view of EUV light being likely to attenuate in the atmosphere. At this time, if particles are attaching to the pattern of the mask MK, the production yield of semiconductor devices manufactured using the mask MK will be affected adversely. Although pellicles for EUV masks are being developed, with loss of the amount of EUV light being large, it is hardly a good measure to cover the pattern surface MKa of the mask MK with a pellicle so as to reduce particles attaching to the pattern of the mask MK in number.

In the present embodiment, in order to reduce particles attaching to the pattern of the mask MK in number, the mask case 1 of a dual structure called a dual pod structure is used to house the mask MK. The way of housing is to house the mask MK in an inner pod (e.g., an EIP: EUV Inner Pod) 10 as shown in 1A and 1B of FIG. 1. The inner pod 10 is formed of, e.g., material composed mainly of metal. The inner pod 10 has a base 12 and a cover 11, and the mask MK, with the pattern surface MKa facing down, is sandwiched between the base 12 and the cover 11 to be housed. Then, the inner pod 10 is further housed in an outer pod 20 as shown in 1B and 1C of FIG. 1. The outer pod 20 is formed of, e.g., material composed mainly of resin. The outer pod 20 has a base 22 and a cover 21, and the inner pod 10 is sandwiched between the base 22 and the cover 21 to be housed. With the mask case 1 of this dual structure, it can be made difficult for particles to get into the space around the mask MK from the outside when the mask MK is kept therein.

Further, the inner pod 10 is configured such that it is difficult for particles present in the space around the mask MK to attach to the pattern of the mask MK while the mask MK is housed therein. The inner pod 10 has a plurality of guide members GD11, GD12, GD21, GD22, GD31, GD32, GD41, GD42, and a plurality of support members SP1, SP2, SP3, SP4 as shown in 2A and 2B of FIG. 2. The guide members GD11 to GD42 position the mask MK in housing the inner pod 10 in the mask MK as shown in 2A and 2C of FIG. 2. The guide members GD11 to GD42 position the mask MK in such a position that the inner pod 10 easily houses the mask MK, that is, the mask MK is included inside the base 12 in plan view. Not being limited to the conical shape illustrated in FIG. 2, the guide members GD11 to GD42 may be in another shape (such as a pyramid, column, or plate shape) as long as the positioning is possible. In 2A to 2C of FIG. 2, two orthogonal directions in the pattern surface MKa of the mask MK are referred to as an X direction and a Y direction, and a direction perpendicular to the pattern surface MKa of the mask MK is a Z direction.

With the mask MK being positioned by the guide members GD11 to GD42, the support members SP1 to SP4 support the mask MK, securing a clearance CL between the pattern surface MKa of the mask MK and the upper surface 12a of the base 12. Not being limited to the sphere shape illustrated in FIG. 2, the support members SP1 to SP4 may be in another shape (such as a rectangular parallelepiped or plate shape) as long as they can support the mask MK securing the clearance CL. The support members SP1 to SP4 keep the clearance CL at, e.g., about several tens to a hundred pm. Securing the clearance CL between the pattern surface MKa of the mask MK and the base 12 of the inner pod 10 makes it possible to avoid the pattern of the mask MK touching the base 12, thus preventing the pattern of the mask MK from being harmed. Further, by making the clearance CL small, it can be made difficult for gas, in an area 90 where the pattern of the mask MK and the base 12 face each other, to move, because of viscosity or the like of the gas. Thus, gas, etc., getting into the area 90 from outside the area 90 is more likely to be suppressed, and therefore particles getting into the vicinity of the pattern of the mask MK can be prevented.

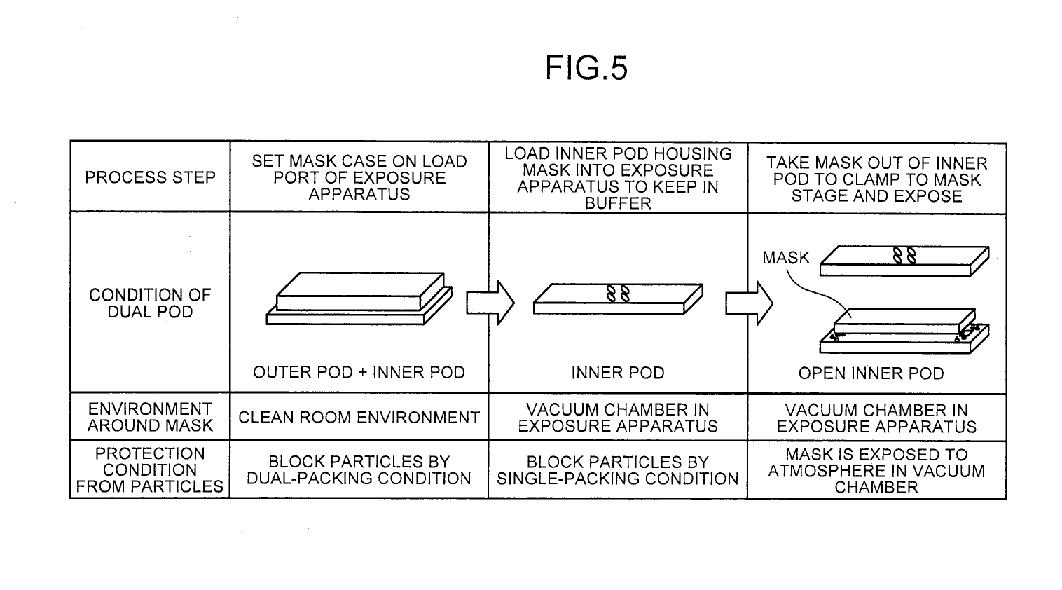

In contrast, in the process in which the inner pod 10 is opened so that the mask MK is taken out of the inner pod 10, there is the possibility that particles attach to the base 12 of the inner pod 10 or the mask MK as shown in FIGS. 4 and 5. FIG. 4 is a diagram showing the configuration of the exposure apparatus 100 in which the mask MK is used. FIG. 5 is a figure showing particles' attaching to the mask MK.

For example, in loading the mask MK into the exposure apparatus (EUV exposure apparatus) 100, after the mask case 1 is set on a load port 101, the inner pod 10 is taken out of the outer pod 20 in such a way that the inner pod 10 touches the outside air, and the inner pod 10 with the mask MK housed therein is made to wait in a buffer 104 in the exposure apparatus 100. Then, when exposure is about to be performed, the mask MK is taken out of the inner pod 10, and after the back side of the mask MK opposite to the pattern surface MKa is clamped to an electrostatic chuck portion of a mask stage 105, exposure is performed, and after the exposure finishes, the mask MK is housed in the inner pod 10 again.

At this time, particles attaching to the mask stage 105 may then move from the mask stage 105 side onto the pattern surface MKa of the mask MK as indicated by a broken-line arrow in FIG. 4. At the open/close timing of gate valves 103, 109, particles in the vacuum chamber of the exposure apparatus 100 may flow or move into the vicinity of the mask MK or the inner pod 10 and attach thereto. Further, since the mask MK is in contact with the support members SP1 to SP4 of the inner pod 10, particles originating in the support members SP1 to SP4 may attach to the mask MK or the base 12 of the inner pod 10. Yet further, because in the EUV exposure apparatus 100 the mask MK is kept in a vacuum, particles are more likely to get in between the pattern surface MKa of the mask MK and the inner pod 10.

Hence, even if the mask case 1 of the dual pod structure is used, particles may be attaching to the mask MK or the inner pod 10 after the mask MK is used in the exposure process. Accordingly, in order to determine the condition of particles attaching to the pattern of the mask MK, particles attaching to the base 12 of the inner pod 10 need to be highly accurately inspected for. At this time, for the purpose of reducing the production cost of semiconductor devices, it is desired to perform particle inspection on the base 12 of the inner pod 10 using the same optical inspection apparatus as is used in particle inspection of the back surface MKb of the mask MK.

However, protrusion-like structures such as the guide members GD11 to GD42 and the support members SP1 to SP4 are provided on the base 12 of the inner pod 10 at the upper surface 12a thereof as shown in 2A to 2C of FIG. 2. When using an optical inspection apparatus, the scattering of light by these protrusion-like structures is likely to affect the inspection. Hence, it is difficult to perform particle inspection on the base 12 of the inner pod 10 using an optical inspection apparatus.

Suppose that an inspection member having a flat surface separate from the inner pod 10 is prepared and is also washed when the inner pod 10 is washed to perform particle inspection on the inspection member, thereby indirectly performing particle inspection on the base 12 of the inner pod 10. As the inspection member, for example, a plate-shaped member formed of the same material as the inner pod 10 can be used. In this case, because there is almost no correlation between particles attaching to the plate-shaped member and particles attaching to the base 12, it is difficult to determine whether the base 12 of the inner pod 10 has been washed enough. Further, it is difficult to obtain position-size information of particles remaining on the base 12 of the inner pod 10.

Accordingly, in the first embodiment, a dug area 121 is provided in a part of the mask case 1 facing the pattern of the mask MK therein so that an inspection plate 30 is fitted into the dug area 121 when housing the mask MK therein and that, in inspection, the inspection plate 30 can be detached out of the dug area 121 to be inspected with an optical inspection apparatus.

Specifically, the base 12 of the inner pod 10 has the dug area 121 in a part of its upper surface 12a facing the pattern of the mask MK as shown in 1A of FIG. 1. The dug area 121 is an area formed to be further back than the upper surface 12a by digging a hole in the upper surface 12a of a plate-shaped member as the base 12. The dug area 121 covers at least part of the exposure feasible area MKe when seen through the mask MK in a direction (Z direction) perpendicular to the pattern surface MKa thereof as shown in 2C of FIG. 2. The mask case 1 further comprises the inspection plate 30 detachably fitted in the dug area 121. As shown in 2A, 2B of FIG. 2, the dug area 121 has planar dimensions corresponding to those of the inspection plate 30. For example, the dug area 121 may have planar dimensions that are the planar dimensions of the inspection plate 30 plus tolerances, respectively. The inner pod 10 houses the mask MK with the inspection plate 30 being fitted in the dug area 121 of the base 12, as shown in 1A, 1B of FIGS. 1 and 2A of FIG. 2. Therefore, particles having a correlation with particles attaching to the pattern of the mask MK can be made to attach to the inspection plate 30.

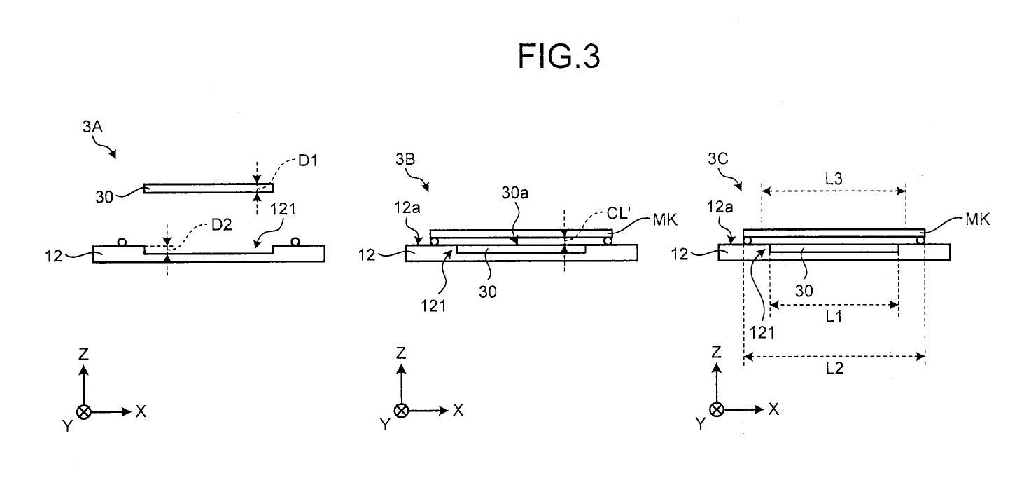

For example, as shown in 2C of FIGS. 2 and 3C of FIG. 3, the dug area 121 is includes in the mask MK when seen through the mask MK in a direction (Z direction) perpendicular to the pattern surface MKa thereof. FIG. 3 is a diagram showing a cross-sectional configuration of the dug area 121, and 3C of FIG. 3 is a diagram showing a cross-sectional configuration taken along line A-A in 2C of FIG. 2. In 3C of FIG. 3, the guide members are omitted from the figure for simplicity of illustration. The dug area 121 corresponds to the exposure feasible area MKe when seen through the mask MK in a direction (Z direction) perpendicular to the pattern surface MKa thereof. That is, the dimension L1 along the X direction of the dug area 121 is approximately equal to the dimension L3 along the X direction of the exposure feasible area MKe. The dimensions L1 and L3 are both smaller than the dimension L2 along the X direction of the mask MK. The dimension L4 along the Y direction of the dug area 121 is approximately equal to the dimension L6 along the Y direction of the exposure feasible area MKe. The dimensions L4 and L6 are both smaller than the dimension L5 along the Y direction of the mask MK. Therefore, a correlation between particles attaching to the inspection plate 30 and particles attaching to the pattern of the mask MK can be improved.

Further, the dug area 121 is located away from the support members SP1 to SP4 as shown in 2A and 2B of FIG. 2. The dug area 121 is located away from the guide members GD11 to GD42. In the area 90 sandwiched between the mask MK and the base 12 when the mask MK is housed, particles are less likely to get into the vicinities of the support members SP1 to SP4 and the guide members GD11 to GD42 than into the area inward of them. Thus, with effectively suppressing particles getting into the area 90, the dug area 121 can be reduced to what corresponds to the exposure feasible area MKe.

Further, the dug area 121 is formed in such a way that, with the inspection plate 30 being fitted in the dug area 121, the surrounding surface (upper surface) 12a of the dug area 121 and the surface 30a of the inspection plate 30 are at substantially the same height. The dug area 121 has a depth D2 corresponding to the thickness Dl of the inspection plate 30 as shown in 3A of FIG. 3. The 3A of FIG. 3 is a diagram showing the condition where, with the mask MK being removed, the inspection plate 30 is detached out of the dug area 121 for a cross-sectional configuration taken along line A-A in 2C of FIG. 2. For example, the depth D2 of the dug area 121 is approximately equal to the thickness D1 of the inspection plate 30. Thus, with the inspection plate 30 being fitted in the dug area 121, the surrounding surface 12a of the dug area and the surface 30a of the inspection plate 30 can be at substantially the same height as shown in 3B of FIG. 3. The 3B of FIG. 3 is a diagram showing a cross-sectional configuration taken along line A-A in 2C of FIG. 2. That is, the clearance CL′ between the pattern surface MKa of the mask MK and the surface 30a of the inspection plate 30 can be made approximately equal to the clearance CL between the pattern surface MKa of the mask MK and the upper surface 12a of the base 12.

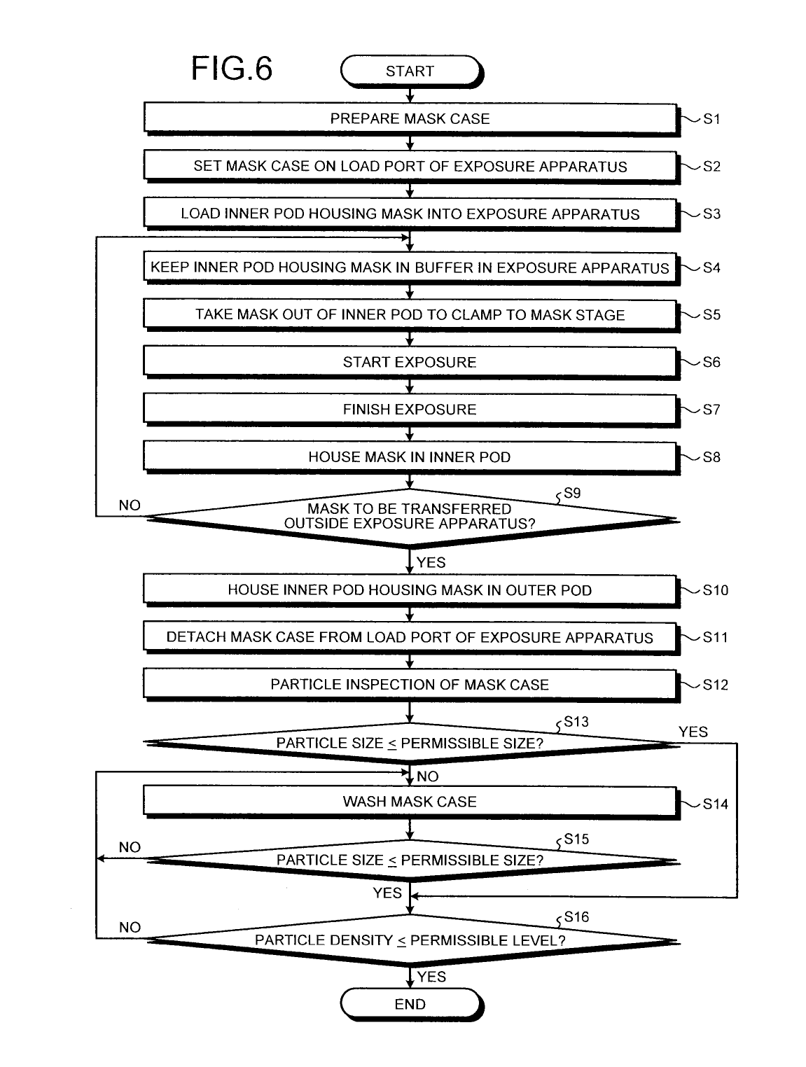

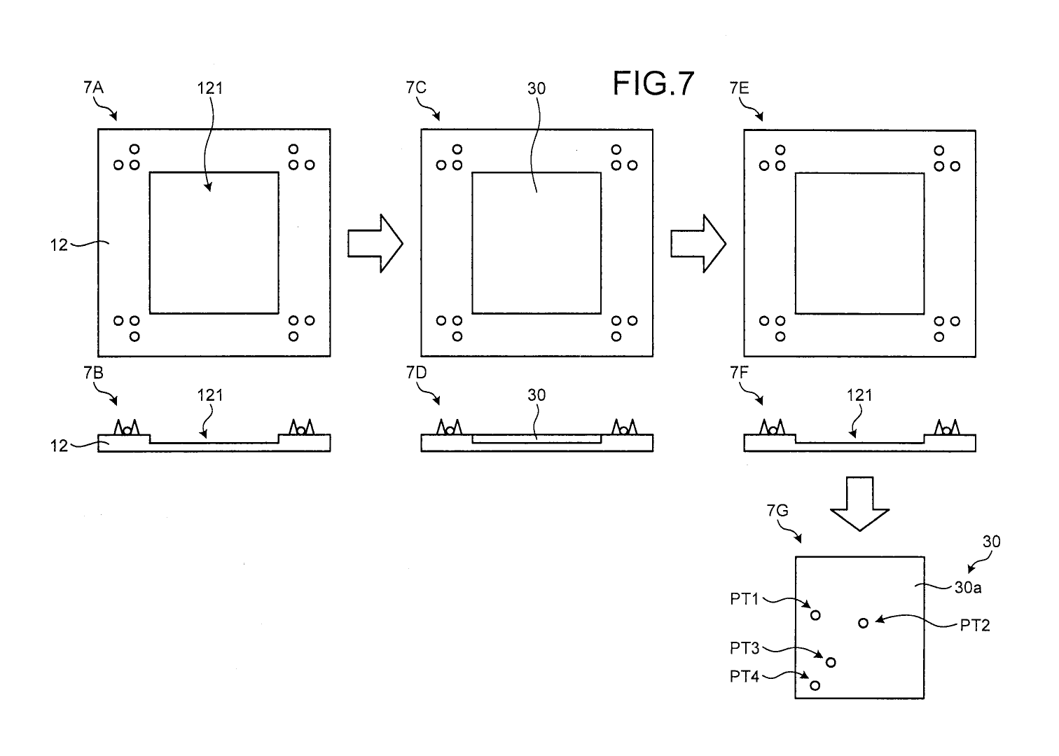

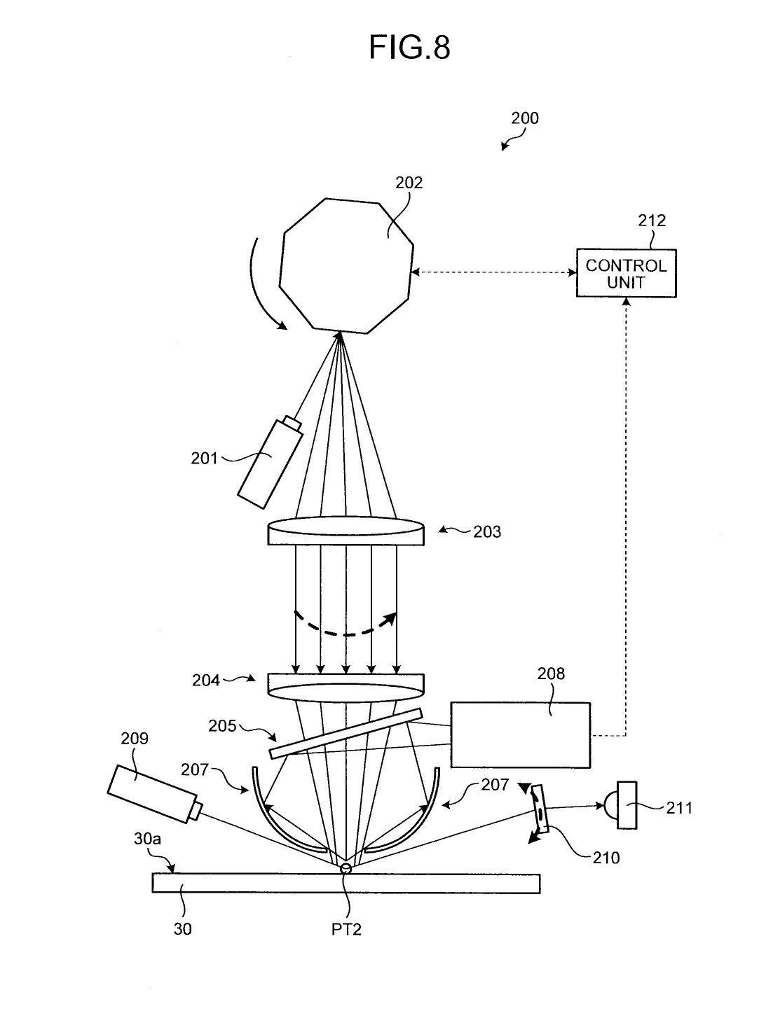

Next, a usage method and inspection method of the mask case 1 will be described using mainly FIGS. 6 to 8. FIG. 6 is a flow chart showing the usage method and inspection method of the mask case 1. FIG. 7 is a diagram showing the inspection method of the mask case 1. FIG. 8 is a diagram showing the configuration of an inspection apparatus for performing particle inspection.

The inspection plate 30 is fitted into the dug area 121 of the base 12 as shown in 7A to 7D of FIG. 7. In this condition, as shown in 1A to 1C of FIG. 1, the mask MK is housed in the inner pod 10, and the inner pod 10 is housed in the outer pod 20 so that the mask case 1 of the dual pod structure is prepared (S1). The mask case 1 is set on the load port 101 of the exposure apparatus 100 (see FIG. 4) (S2). The load port 101 is loaded into a load lock chamber 102 to be accommodated therein, and the inside of the load lock chamber 102 is vacuumized (S3). Without the inner pod 10 touching the outside air, the gate valves 103 is opened, and the inner pod 10 is taken out of the outer pod 20 to be accommodated in the buffer 104 in the exposure apparatus 100 and is made to wait (S4).

Then, when exposure is about to be performed, the mask MK is taken out of the inner pod 10, and the back side of the mask MK opposite to the pattern surface MKa is clamped to the electrostatic chuck portion of the mask stage 105 (S5). Then, exposure of a substrate SB is started (S6). That is, with the mask MK being held on the mask stage 105 and the substrate SB being held on a substrate stage 108, the gate valve 109 is opened so as to lead EUV light from a light source 110 to an illumination optical system 106. The mask MK is illuminated by the illumination optical system 106 to transfer the pattern of the mask MK via a projection optical system 107 onto the substrate SB. By this means, exposure is performed on the substrate SB. Then, the gate valve 109 is closed to finish the exposure process of the substrate SB (S7). The mask MK, with the pattern surface MKa facing down, is housed in the inner pod 10 (S8). The exposure apparatus 100 determines whether the mask MK is to be transferred outside the exposure apparatus 100 (S9). If the mask MK is not to be transferred out (No at S9), the exposure apparatus 100 makes the process return to S4.

If the mask MK is to be transferred out (Yes at S9), the exposure apparatus 100 makes the process proceed to S10. The exposure apparatus 100 opens the gate valve 103 and loads the inner pod 10 into the load lock chamber 102 to house in the outer pod 20 so that the mask case 1 takes back on the dual pod structure (S10). Then, the gate valve 103 is closed, and the mask case 1 is transferred from the load lock chamber 102 outside the exposure apparatus 100 (S11). The mask case 1 is opened to take the inspection plate 30 out of the dug area 121 of the base 12 as shown in 7E to 7G of FIG. 7. The 7G of FIG. 7 shows illustratively the condition where particles PT1 to PT4 are attaching onto the surface 30a of the inspection plate 30. Particle inspection is performed on the inspection plate 30 with an inspection apparatus 200 as shown in FIG. 8 (S12).

In the inspection apparatus 200, a laser light beam emitted from a for-inspection laser light source 201 is reflected by a polygon mirror 202 rotating at high speed and passes through a collimator lens 203, an objective lens 204, and a half mirror 205 to be irradiated onto the surface 30a of the inspection plate 30. The position through which the laser passes can be changed by the rotation angle of the polygon mirror 202, and thus laser light can be scanned across the surface 30a of the inspection plate 30. At this time, if a particle exists on the surface 30a of the inspection plate 30, scattered light is produced and condensed by a curved mirror 207 and the half mirror 205 to be received by a scattered light detecting unit 208. FIG. 8 shows illustratively the condition where scattered light is produced by particle PT2. The focus adjustment of the for-inspection laser light is performed by adjusting the angle of a glass plate 210 so that laser light emitted from a for-auto-focus laser light source 209 is incident on a for-auto-focus receiving unit 211 and calculating a focus value using the adjustment value.

The control unit 212 can determine the presence/absence and position of a particle on the surface 30a of the inspection plate 30 to be associated with each other according to the amount of received light of the scattered light detecting unit 208 and the rotation angle of the polygon mirror 202. Further, the control unit 212 can infer the external dimension of the particle according to information such as the rotation speed of the polygon mirror 202 and the time period during which the scattered light detecting unit 208 was detecting an amount of scattered light equal to or greater than the reference light amount.

With particle inspection performance, the control unit 212 of the inspection apparatus 200 determines whether the external dimension of the particle (particle size) is within a permissible size (S13). The permissible size can be set to correspond to, e.g., the clearance CL between the pattern surface MKa of the mask MK and the upper surface 12a of the base 12 and the clearance CL′ between the pattern surface MKa and the upper surface 30a of the inspection plate 30. For example, if the particle size is greater than the clearances CL, CL′, it can be inferred that the particle can harm the pattern of the mask MK, and hence the permissible size can be set at a value approximately equal to the clearances CL, CL′. If the particle size is within the permissible size (Yes at S13), the inspection apparatus 200 makes the process proceed to S16.

If the particle size exceeds the permissible size (No at S13), the inspection apparatus 200 makes the process proceed to S14. That is, the base 12 and cover 11 of the inner pod 10, the base 22 and cover 21 of the outer pod 20, the inspection plate 30, and the mask MK are rinsed with pure water by a washing apparatus (not shown) (S14).

Then, particle inspection is again performed on the inspection plate 30 with the inspection apparatus 200 shown in FIG. 8. With the particle inspection performance, the control unit 212 of the inspection apparatus 200 determines whether the external dimension of the particle (particle size) is within a permissible size (S15). If the particle size exceeds the permissible size (No at S15), the inspection apparatus 200 makes the process return to S14. If the particle size is within the permissible size (Yes at S15), the inspection apparatus 200 makes the process proceed to S16.

Then, the inspection apparatus 200 determines whether particle density is not greater than a permissible level (S16). If the particle density exceeds the permissible level (No at S16), the inspection apparatus 200, determining that further rinsing is needed, makes the process return to S14. If the particle density is not greater than the permissible level (Yes at S15), the inspection apparatus 200, determining that enough rinsing has been performed, finishes the process.

It should be noted that the inspection apparatus 200 can further identify the position on the surface 30a of the inspection plate 30 at which a particle size exceeding the permissible size has been detected at S15. In this case, the inspection apparatus 200 can obtain the position on the pattern surface MKa of the mask MK corresponding to the identified position, after S16. Then, the inspection apparatus 200 performs particle inspection on the pattern surface MKa of the mask MK with a focus on the position on mask MK corresponding to the identified position on the inspection plate 30. Thus, the inspection time for the mask MK can be shortened as compared with the case where the entire pattern surface MKa of the mask MK is inspected.

As described above, in the first embodiment, the mask case 1 has the dug area 121 in its part facing the pattern of the mask MK. While the mask MK is housed, the dug area 121 covers at least part of the exposure feasible area MKe in the pattern surface MKa of the mask MK when seen through the mask MK in a direction (Z direction) perpendicular to the pattern surface MKa thereof. The inspection plate 30 is fitted into the dug area 121 when housing the mask MK. Thus, particles having a correlation with particles attaching to the pattern of the mask MK can be made to attach to the surface 30a of the inspection plate 30. Therefore, the condition of particles attaching to the pattern of the mask MK can be determined by inspecting the surface 30a of the inspection plate 30, and thus it can be determined whether or not the inspection of the pattern surface MKa of the mask MK is necessary, so that the frequency of inspection of the pattern surface MKa of the mask MK, which takes much time, can be reduced.

Further, in the first embodiment, in the mask case 1, while the mask MK is housed, the dug area 121 is includes in the mask MK when seen through the mask MK in a direction (Z direction) perpendicular to the pattern surface MKa thereof. The dug area 121 corresponds to the exposure feasible area MKe when seen through the mask MK in a direction perpendicular to the pattern surface MKa thereof. Therefore, a correlation between particles attaching to the inspection plate 30 and particles attaching to the pattern of the mask MK can be improved.

Yet further, in the first embodiment, in the mask case 1, the dug area 121 is located away from the support members SP1 to SP4. The dug area 121 is located away from the guide members GD11 to GD42. Thus, with effectively suppressing particles getting into the area 90, the dug area 121 can be reduced to what corresponds to the exposure feasible area MKe.

Still further, in the first embodiment, in the mask case 1, the dug area 121 is formed such that, with the inspection plate 30 being fitted in the dug area 121, the surrounding surface (upper surface) 12a of the dug area 121 and the surface 30a of the inspection plate 30 are at substantially the same height. That is, the dug area 121 has the depth D2 corresponding to the thickness D1 of the inspection plate 30. Therefore, the clearance CL′ between the pattern surface MKa of the mask MK and the surface 30a of the inspection plate 30 can be made approximately equal to the clearance CL between the pattern surface MKa of the mask MK and the upper surface 12a of the base 12. As a result, it can be made difficult for gas, in the area where the pattern of the mask MK and the surface 30a of the inspection plate 30 face each other, to move, because of viscosity and the like of the gas.

Further, in the first embodiment, in the inspection method of the mask case 1, with the inspection plate 30 being fitted in the dug area 121, the mask MK is housed in the mask case 1, and thereafter the inspection plate 30 is detached out of the dug area 121, and particles attaching to the surface of the inspection plate 30 are inspected for. The particle inspection determines the presence/absence of a particle on the surface 30a of the inspection plate 30 and the position of the particle and also the external dimension of the particle. Thus, if the external dimension of the particle exceeds the clearance CL′ between the pattern surface MKa of the mask MK and the upper surface 30a of the inspection plate 30, or so on, it can be determined whether the pattern surface MKa of the mask MK needs to be inspected, and hence the frequency of inspection of the pattern surface MKa of the mask MK, which takes much time, can be reduced.

Further, in the first embodiment, in the inspection method of the mask case 1, after exposure is performed, particle inspection is performed before and after rinsing the mask MK and the mask case 1. With this process, information about the effect of the mask case 1 being rinsed and about residual particles can be more accurately found out. That is, the accuracy in the determination whether the mask case 1 has been rinsed enough can be improved, and the number of rinse times can be reduced to a requisite minimum, so that the lead time of manufacturing a semiconductor device using the mask MK can be easily shortened. Yet further, with particles attaching to the pattern of the mask MK being suppressed, exposure can be performed, and hence pattern formation failures can be avoided, so that the cost of semiconductor device production with use of the mask MK can be easily reduced.

It should be noted that, although the first embodiment illustrates the case where the mask case 1 is of the dual pod structure, the invention is not limited to this. That is, the concept of the first embodiment can be applied to mask cases of other structures that house a mask for an exposure apparatus that exposes a semiconductor or liquid crystal panel through the pattern of the mask and wherein the movement of particles to the mask side is expected. Also, the concept of the first embodiment can be applied to cases for templates used in a nano-imprint technique that forms a pattern of a resist coated on a semiconductor substrate by pressing the template against the resist and irradiating UV light or the like.

Or, as shown in 2C of FIGS. 2 and 3C of FIG. 3, the area of the clearance CL where the pattern surface MKa of the mask MK and the upper surface 12a of the base 12 face each other, surrounds the area of the clearance CL′ where the pattern surface MKa of the mask MK and the surface 30a of the inspection plate 30 face each other when seen through the mask MK in a direction perpendicular to the pattern surface MKa thereof. Hence, if the area of the clearance CL can sufficiently block the outside air's flowing into the area of the clearance CL′, the clearance CL′ may be different from the clearance CL. In this case, the thickness of the inspection plate 30 and the depth of the dug area 121 can have degrees of freedom.

### Second Embodiment

Next, a mask case 300 according to the second embodiment will be described. Description will be made below focusing on the differences from the first embodiment.

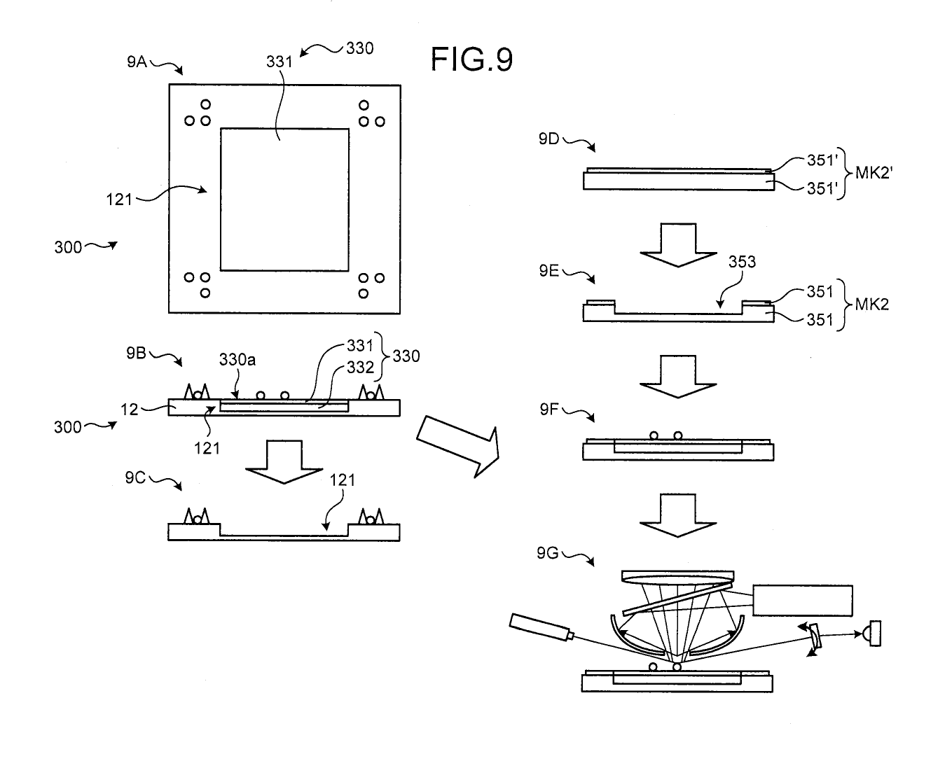

The second embodiment presents new means to make the characteristics of inspection of the mask case 300 by the inspection apparatus 200 closer to the inspection characteristics of the mask. Specifically, the mask case 300 has an inspection plate 330 shown in 9A, 9B of FIG. 9 instead of the inspection plate 30 (see FIG. 2). The inspection plate 330, at least the surface 330a thereof, is formed of material having substantially the same light reflectance as the material used for the back surface MKb of the mask MK. That is, the inspection plate 330 has a substrate 332 and a film 331. The film 331 is placed on the surface of the substrate 332. The film 331 is formed of material having substantially the same light reflectance as the material used for the back surface MKb of the mask MK.

Although not mentioned in, e.g., the first embodiment, in order to make the back surface MKb of the mask MK stuck onto the mask stage 105 by the electrostatic chuck, a metal film of Cr, etc., may be formed on the back surface MKb. In this case, the film 331 can be formed of metal such as Cr. Thus, the characteristics of inspection of the inspection plate 330 by the inspection apparatus 200 can be made closer to the inspection characteristics of the mask MK.

Further, as shown in 9D of FIG. 9, a mask MK2′ having substantially the same structure as the mask MK to be housed in the mask case 300 is prepared. The mask MK2′ has a substrate 352′ and a film 351′. The film 351′ covers the back side of the substrate 352′. Although not shown, a Mo/Si multilayer for reflecting EUV light and an absorber for absorbing EUV light may be formed on the front side of the substrate 352′. A dug area 353 into which to fit the inspection plate 330 is formed in an area of the mask MK2′ corresponding to the exposure feasible area MKe of the mask MK. The dug area 353 has planar dimensions corresponding to the inspection plate 330. The dug area 353 has a depth corresponding to the thickness of the inspection plate 330. Thus, a mask (second mask) MK2 having the dug area (second dug area) 353 and also a substrate 352 and a film 351 is prepared.

Further, the inspection method of the mask case 300 is different from that of the first embodiment in the following point as shown in FIG. 9. FIG. 9 is a diagram showing the inspection method of the mask case 300. In S12 shown in FIG. 6, the mask case 300 is opened, and the inspection plate 330 is taken out of the dug area 121 of the base 12 as shown in 9A to 9C of FIG. 9. Then, the inspection plate 330 is fitted into the dug area 353 of the mask MK2 as shown in 9E, 9F of FIG. 9. In this condition, particle inspection is performed on the inspection plate 330 with the inspection apparatus 200 shown in FIG. 8, as shown in 9G of FIG. 9.

As described above, in the second embodiment, the inspection plate 330, at least the surface 330a thereof, is formed of material having substantially the same light reflectance as the material used for the back surface MKb of the mask MK. Thus, the characteristics of inspection of the inspection plate 330 by the inspection apparatus 200 can be made closer to the inspection characteristics of the mask MK.

Further, in the second embodiment, the inspection plate 330 has the film 331, formed of material having substantially the same light reflectance as the material used for the back surface MKb of the mask MK, on the surface of the substrate 332. With this arrangement, at least the surface 330a of the inspection plate 330 can be formed of material having substantially the same light reflectance as the material used for the back surface MKb of the mask MK.

Further, in the second embodiment, in the inspection method of the mask case 300, with the inspection plate 330 detached out of the dug area 121 being fitted in the dug area 353 of the mask MK2, particles attaching to the inspection plate 330 are inspected for with the inspection apparatus 200. With this process, the characteristics of inspection of the inspection plate 330 by the inspection apparatus 200 can be made closer to the inspection characteristics of the mask MK without the need to prepare an inspection apparatus exclusive to mask cases or an inspection apparatus comprising a transfer system.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mask case to house a mask for an exposure apparatus, wherein
the mask case has a dug area in its part to face a pattern of the mask.

2. The mask case according to claim 1, wherein
the dug area covers at least part of an exposure feasible area in a pattern surface of the mask when seen through the mask in a direction perpendicular to the pattern surface thereof.

3. The mask case according to claim 2, wherein
the dug area is included in the mask when seen through the mask in a direction perpendicular to the pattern surface.

4. The mask case according to claim 3, wherein
the dug area corresponds to the exposure feasible area when seen through the mask in a direction perpendicular to the pattern surface.

5. The mask case according to claim 1, comprising:
an inner pod to house the mask; and
an outer pod that houses the inner pod,
wherein the inner pod has the dug area in its part to face the pattern of the mask.

6. The mask case according to claim 5, wherein
the inner pod has support members to secure a clearance between the pattern of the mask and the inner pod when the inner pod houses the mask, and
wherein the dug area is located away from the support members.

7. The mask case according to claim 5, wherein
the inner pod has guide members to position the mask when the inner pod houses the mask, and
wherein the dug area is located away from the guide members.

8. The mask case according to claim 1, further comprising a plate that is detachably fitted into the dug area.

9. The mask case according to claim 8, wherein
the dug area has a depth corresponding to a thickness of the plate.

10. The mask case according to claim 8, wherein
the mask case comprises:
an inner pod to house the mask; and
an outer pod that houses the inner pod,
wherein the inner pod has the dug area in its part to face the pattern of the mask, and
wherein the dug area is formed such that, with the plate being fitted in the dug area, a surrounding surface of the dug area and a surface of the plate are at substantially a same height.

11. The mask case according to claim 8, wherein
the plate, at least a surface thereof, is formed of material having substantially a same light reflectance as material used for a surface opposite to a pattern surface of the mask.

12. The mask case according to claim 11, wherein
the plate has:
a substrate; and
a film laid on a surface of the substrate and formed of the material having substantially a same light reflectance as the material used for the surface opposite to the pattern surface of the mask.

13. An inspection method of inspecting a mask case to house a mask for an exposure apparatus, the method comprising:
housing the mask in the mask case with an inspection plate being fitted in a dug area provide in a part of the mask case to face a pattern of the mask; and
inspecting for particles attaching to a surface of the inspection plate, by opening the mask case and detaching the inspection plate out of the dug area.

14. The inspection method according to claim 13, wherein
the inspecting includes determining presence/absence of a particle on the surface of the inspection plate and a position of the particle.

15. The inspection method according to claim 13, wherein
the inspecting includes determining external dimension of a particle on the surface of the inspection plate.

16. The inspection method according to claim 13, wherein
the inspecting is performed using an inspection apparatus that is used to inspect for particles on a surface opposite to a pattern surface of the mask.

17. The inspection method according to claim 16, wherein
the inspecting includes inspecting for particles attaching to the inspection plate using the inspection apparatus with the inspection plate detached out of the dug area being fitted into a second dug area provided in a surface to be inspected of a second mask.

18. The inspection method according to claim 17, wherein
the inspection plate, at least the surface thereof, is formed of material having substantially a same light reflectance as material used for the surface to be inspected of the second mask.

19. The inspection method according to claim 13, further comprising:
washing the mask case,
wherein the inspecting is performed before and after the washing.

20. The inspection method according to claim 13, further comprising:
performing exposure to transfer the pattern of the mask onto a substrate by illuminating the mask with an illumination optical system, by opening the mask case and making the mask held on a mask stage in the exposure apparatus,
wherein the inspecting is performed after the performing exposure.
